(19) United States
(12) Patent Application Publication
(10) Pub. No.: US 2008/0283904 A1
(43) Pub. Date: Nov. 20, 2008

(54) TWO-BIT FLASH MEMORY CELL AND METHOD FOR MANUFACTURING THE SAME

(76) Inventors: Ming-Cheng Chang, Taipei County (TW); Wei-Ming Liao, Taipei City (TW); Jer-Chyi Wang, Taoyuan County (TW); Chien-Chang Huang, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/828,334

(22) Filed: Jul. 25, 2007

(30) Foreign Application Priority Data
May 16, 2007 (TW) 096117416

(51) Int. Cl. H01L 29/792

(52) U.S. Cl. 257/326; 257/E29.309

(57) ABSTRACT

A two-bit flash memory cell includes a substrate, a gate oxide layer disposed on the substrate, a gate stacked on the gate oxide layer. A charge storage spacer stack is disposed at either side of the gate. The charge storage spacer stack includes a bottom charge storage layer and an upper spacer layer. An insulating layer is disposed between the charge storage spacer stack and the gate. A liner is disposed underneath the bottom charge storage layer. A source/drain region is disposed at one side of the bottom charge storage layer within the substrate.

### BACKGROUND OF THE INVENTION

1. Field of the Invention

The present invention relates to flash memory and fabrication method thereof. More particularly, the present invention relates to a two-bit flash memory cell utilizing sidewall storage mechanism and method for manufacturing the same.

2. Description of the Prior Art

Non-volatile memory is computer memory that can retain the stored information even when not powered. Examples of non-volatile memory include flash memory and electically erasable programmable read only memory (EEPROM). Flash memory is non-volatile memory that can be electrically erased and reprogrammed. It is a technology that is primarily used in memory cards or USB flash drives, which are used for general storage and transfer of data between computers and other digital products. Unlike EEPROM, it is erased and programmed in blocks consisting of multiple locations (in early flash the entire chip had to be erased at once). Flash memory costs far less than EEPROM and therefore has become the dominant technology wherever a significant amount of non-volatile, solid-state storage is needed.

At present, the flash memory can be sub-classified into two types: stack gate flash memory and split gate flash memory. Generally, a stack gate flash memory cell includes a floating gate for storing charge, an oxide-nitride-oxide (ONO) dielectric layer and a control gate. The floating gate is between the control gate and the substrate. Because the floating gate is isolated by its insulating oxide layer, any electrons placed on it get trapped there and thus store the information.

FIG. 1 is a cross sectional view of a typical stack gate flash memory cell. As shown in FIG. 1, the flash memory cell 10a comprises a stack gate 14a on a P type semiconductor substrate 12a. An N type source 16a and an N type drain 18a are disposed on two sides of the stack gate 14a in the semiconductor substrate 12a. A P type doping region 20a is disposed under the N type drain 18a. The stack gate 14a comprises a tunnel oxide layer 22a, a floating gate 24a, an insulating layer 26a and a control gate 28a.

According to the prior art method, to program the flash memory 10a, a high voltage is applied to the control gate 28a and a fixed voltage is applied to the drain 18a. By doing this, channel hot electrons generated at the junction between the P type doping region 20a and the drain 18a are injected into the floating gate 24a through the tunnel oxide layer 22a. When electrons are on the floating gate 24a, they partially cancel out the electric field coupling from the control gate 28a, which modifies the threshold voltage (Vₜ) of the cell 10a. To erase the data stored in the flash memory 10a, the control gate 28a is typically connected to ground or negative voltages and the drain 16a is connected to a high voltage, thereby repelling the electrons in the floating gate 24a by Fowler-Nordheim tunneling mechanism.

FIG. 2 is a cross sectional view of a typical split gate flash memory cell 30a. As shown in FIG. 2, the flash memory cell 30a comprises a gate oxide layer 32a, a floating gate 34a, a control gate 38a, a drain 42a and a source 44a. The control gate 38a laterally extends to one side of the floating gate 34a to form a lower part between the source 44a and the floating gate 34a and a select gate channel 31a in the silicon substrate 40a. An insulating layer 36a is interposed between the control gate 38a and the floating gate 34a.

As the demand for the small size portable electronic devises such as PDA or mobile phones increases, there is constantly a strong need in this industry to provide high quality and high-density flash memory products, thereby improving the reliability and performance of the electronic products.

### SUMMARY OF THE INVENTION

It is one object of this invention to provide an improved two-bit flash memory structure in order to increase the integration of the flash memory device.

According to the claimed invention, a two-bit flash memory cell structure is disclosed. The two-bit flash memory cell structure includes a semiconductor substrate; a gate oxide layer on the semiconductor substrate; a gate electrode on the gate oxide layer; a first sidewall spacer stack comprising a first charge storage layer at one side of the gate electrode and a first spacer layer disposed directly above the first charge storage layer; a second sidewall spacer stack comprising a second charge storage layer at the other side of the gate electrode and a second spacer layer disposed directly above the second charge storage layer; an insulating layer between the gate electrode and the first spacer stack and between the gate electrode and the second spacer stack; a liner layer between the first charge storage layer and the semiconductor substrate and between the second charge storage layer and the semiconductor substrate, wherein the insulating layer separates the gate oxide layer from the liner layer; a first source/drain doping region in the semiconductor substrate next to the first sidewall spacer stack; and a second source/drain doping region in the semiconductor substrate next to the second sidewall spacer stack.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross sectional view of a typical stack gate flash memory cell.

FIG. 2 is a cross sectional view of a typical split gate flash memory cell.

FIGS. 3-10 are schematic, cross-sectional diagrams showing the process for manufacturing a two-bit flash memory cell according to the preferred embodiment of this invention.

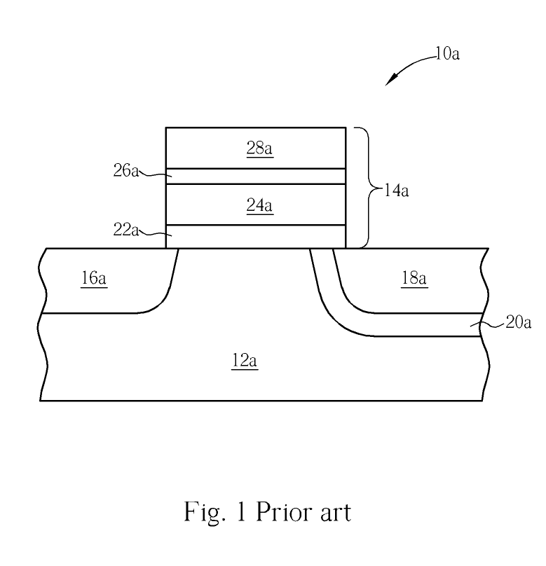

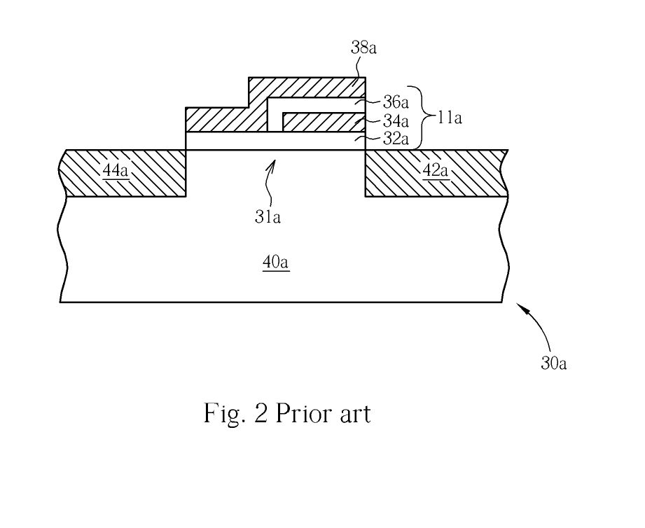

### DETAILED DESCRIPTION

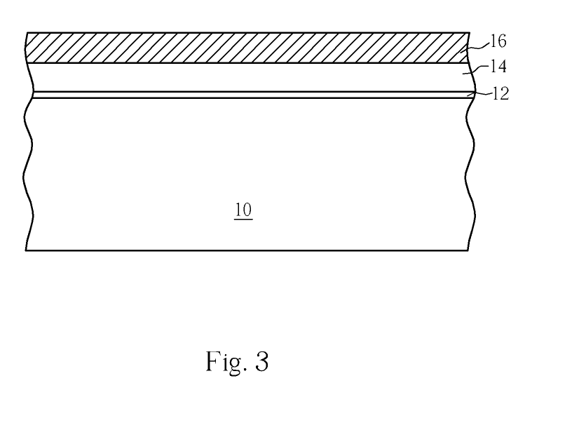

FIGS. 3-10 are schematic, cross-sectional diagrams showing the process for manufacturing a two-bit flash memory cell according to the preferred embodiment of this invention. As shown in FIG. 3, a semiconductor substrate 10 is provided. The semiconductor substrate 10 may be a silicon substrate, a silicon-on-insulator (SOI) substrate, a SiGe semiconductor substrate or the like.

A liner layer 12 is formed on the surface of the semiconductor substrate 10. The liner layer 12 may be a silicon oxide layer. Subsequently, a polysilicon layer 14 such as a doped polysilicon layer is deposited on the liner layer 12. A dielectric layer 16, such as silicon oxide, silicon nitride or oxynitride, is then deposited on the polysilicon layer 14. Preferably, the dielectric layer 16 is a silicon nitride layer.

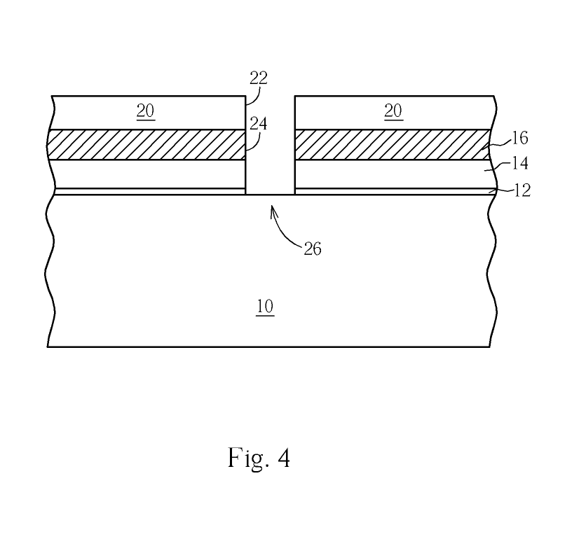

As shown in FIG. 4, a conventional lithographic process is carried out to form a patterned photoresist layer 20 on the dielectric layer 16. The patterned photoresist layer 20 includes an opening 22 that defines a channel region 26 of the two-bit flash memory cell of this invention.

Thereafter, using the photoresist layer 20 as an etching mask, a dry etching process is performed to etch the dielectric layer 16, the polysilicon layer 14 and the liner layer 12 through the opening 22, thereby forming a gate trench 24 therein. The photoresist layer 20 is then stripped.

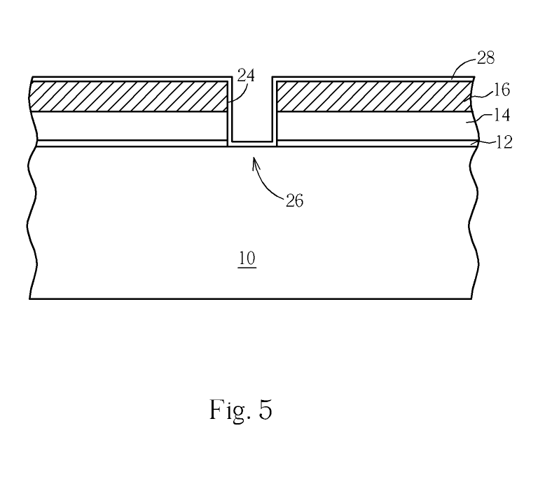

As shown in FIG. 5, a conformal oxide-nitride-oxide (ONO) dielectric layer 28 is formed on the dielectric layer 16 and within the gate trench 24.

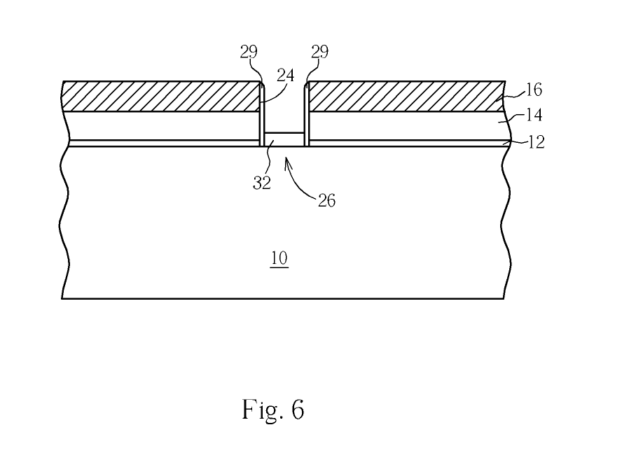

As shown in FIG. 6, a dry etching process is performed to etch the ONO dielectric layer 28 until the surface of the semiconductor substrate 10 is exposed within the gate trench 24, thereby forming an ONO spacer 29 on the vertical sidewall of the gate trench 24. An oxidation process is then carried out to form a gate oxide layer 32 on the exposed surface of the semiconductor substrate 10 within the gate trench 24.

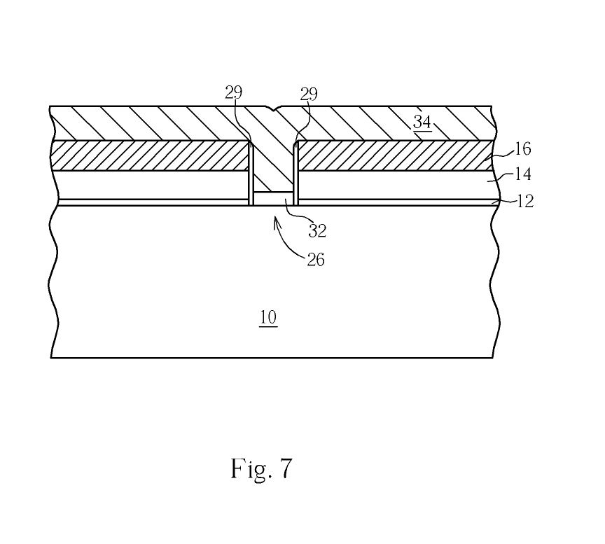

Subsequently, as shown in FIG. 7, a chemical vapor deposition (CVD) process is performed to deposit a polysilicon layer 34 on the dielectric layer 16 and within the gate trench 24. The polysilicon layer 34 fills the gate trench 24.

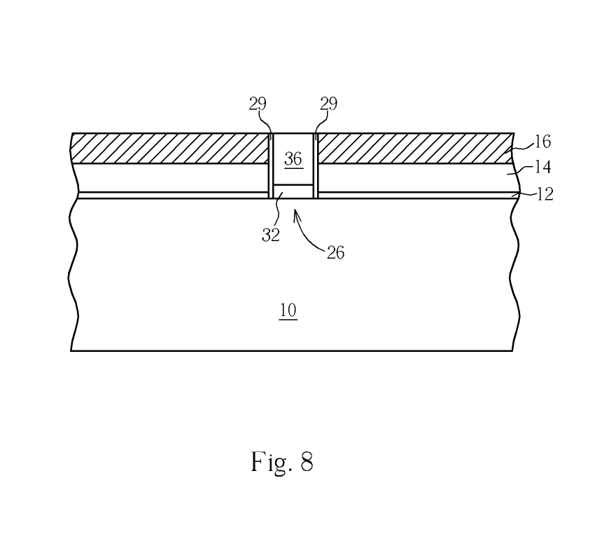

As shown in FIG. 8, using the dielectric layer 16 as a polish stop layer, a chemical mechanical polishing (CMP) is performed to polish the polysilicon layer 34 outside the gate trench 24, thereby forming a polysilicon gate electrode 36. Optionally, a silicide layer (not shown) may be formed on the polysilicon gate electrode 36.

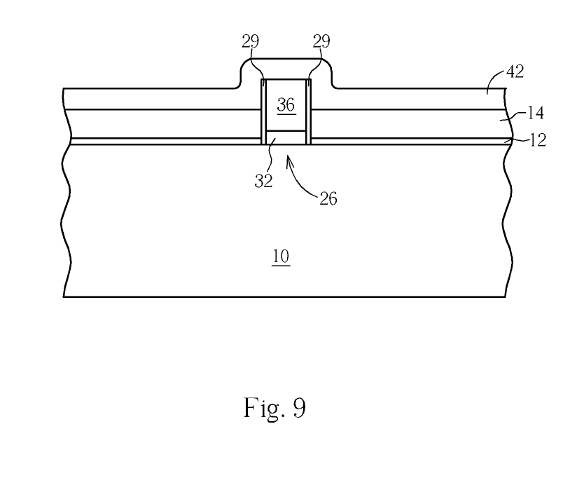

As shown in FIG. 9, an etching process is then performed to strip off the dielectric layer 16. After the dielectric layer 16 is removed, the polysilicon gate electrode 36 protrudes from the top surface of the polysilicon layer 14. Thereafter, a dielectric layer 42 is deposited over the semiconductor substrate 10 to cover the polysilicon layer 14, the polysilicon gate electrode 36 and the ONO spacer 29. The dielectric layer 42 may be silicon oxide.

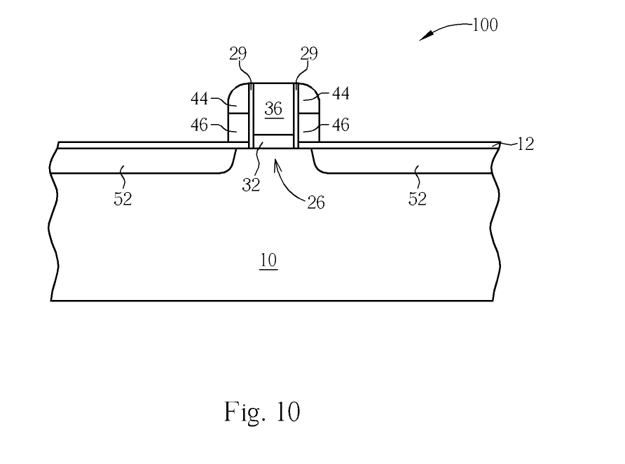

As shown in FIG. 10, a dry etching process is then performed to etch the dielectric layer 42 and the polysilicon layer 14, thereby forming a spacer 44 and a self-aligned polysilicon charge storage layer 46 situated directly under the spacer 44. After the dry etching process is performed, a gate structure 100 of the flash memory cell is completed, wherein the spacer 44 and a self-aligned polysilicon charge storage layer 46 are formed on vertical sidewalls of the polysilicon gate electrode 36 and constitute a sidewall spacer stack. The ONO spacer 29 acts as an insulating layer interposed between the polysilicon gate electrode 36 and the sidewall spacer stack.

Using the gate structure 100 as an ion implant mask, an ion implantation process is performed to implant N type or P type dopants into the semiconductor substrate 10 next to the polysilicon charge storage layer 46, thereby forming a source/drain doping region 52. The channel region 26 is between the source/drain doping regions 52. Preferably, the source/drain doping region 52 partially overlaps with the polysilicon charge storage layer 46 after performing thermal drive-in or activation processes.

Those skilled in the art will readily observe that numerous modifications and alterations of the device and method may be made while retaining the teachings of the invention.

What is claimed is:

1. A two-bit flash memory cell structure comprising:
a semiconductor substrate;
a gate oxide layer on the semiconductor substrate;
a gate electrode on the gate oxide layer;
a first sidewall spacer stack comprising a first charge storage layer at one side of the gate electrode and a first spacer layer disposed directly above the first charge storage layer;
a second sidewall spacer stack comprising a second charge storage layer at the other side of the gate electrode and a second spacer layer disposed directly above the second charge storage layer;
an insulating layer between the gate electrode and the first spacer stack and between the gate electrode and the second spacer stack;
a liner layer between the first charge storage layer and the semiconductor substrate and between the second charge storage layer and the semiconductor substrate, wherein the insulating layer separates the gate oxide layer from the liner layer;
a first source/drain doping region in the semiconductor substrate next to the first sidewall spacer stack; and
a second source/drain doping region in the semiconductor substrate next to the second sidewall spacer stack.

2. The two-bit flash memory cell structure of claim 1 wherein the insulating layer is an oxide-nitride-oxide (ONO) dielectric layer.

3. The two-bit flash memory cell structure of claim 1 wherein the gate electrode is comprised of polysilicon.

4. The two-bit flash memory cell structure of claim 1 wherein the first charge storage layer comprises polysilicon.

5. The two-bit flash memory cell structure of claim 1 wherein the second charge storage layer comprises polysilicon.

6. The two-bit flash memory cell structure of claim 1 wherein the liner layer is a silicon oxide layer.

7. The two-bit flash memory cell structure of claim 1 wherein the first spacer layer comprises silicon oxide.

8. The two-bit flash memory cell structure of claim 1 wherein the second spacer layer comprises silicon oxide.
